(19) United States
(12) Patent Application Publication
(10) Pub. No.: US 2011/0111132 A1
(43) Pub. Date: May 12, 2011

(54) SYSTEM AND METHOD FOR DEPOSITING COATINGS ON INNER SURFACE OF TUBULAR STRUCTURE

(75) Inventors: Ronghua Wei, San Antonio, TX (US); Christopher Rincon, San Antonio, TX (US); Edward Langa, San Antonio, TX (US); Narayana S. Cheruvu, San Antonio, TX (US)

(73) Assignee: ELECTRIC POWER RESEARCH INSTITUTE, INC., Charlotte, NC (US)

(21) Appl. No.: 12/939,248

(22) Filed: Nov. 4, 2010

Related U.S. Application Data
(60) Provisional application No. 61/259,278, filed on Nov. 9, 2009.

(51) Int. Cl. C23C 14/02; B29C 71/04

(52) U.S. Cl. 427/523; 118/723 VE; 427/532; 427/534

(57) ABSTRACT

A system and method for depositing coatings on an inner surface of a tubular structure includes at least one pump for creating and maintaining a vacuum in the tubular structure, a meshed electrode adapted to be positioned in a center of the tubular structure, and a biased voltage power supply connected to the meshed electrode. The biased voltage power supply is adapted to apply a negative voltage to the meshed electrode such that the negative voltage causes a hollow cathode discharge inside the meshed electrode. The creation of the hollow cathode discharge causes ions to be drawn out of a mesh on the meshed electrode and accelerate onto an inner surface of the tubular structure, thereby coating the inner surface with a desired coating.

### BACKGROUND OF THE INVENTION

The present invention relates generally to a system and method for depositing coatings on a tubular structure, and more particularly to a system and method for depositing coatings on an inner surface of a tubular structure that is electrically grounded.

The deposition of hard, erosion and corrosion resistant coatings on tubular structures is well-known in the art. Additionally, inner diameter (ID) surfaces of tubes have been coated with various coatings using various techniques. For example, plasma immersion ion deposition (PIID) processes have been used to coat the ID surfaces of tubes. This process generates plasma so that the gas precursor is dissociated such that ions may be drawn to the tube to form a coating. Typically, the tube is electrically isolated from ground and a negative pulsed voltage is applied to the tube.

In depositing the tube ID surfaces with the PIID process, illustrated in FIG. 1, the tube may be placed in a vacuum chamber, and under certain pressures (a few to a few tens of a millitorr), plasma may be generated by applying a voltage to the tube with respect to ground using either microwave power or more often a train of negative voltage pulses. The latter process is often called the pulsed glow discharge (PGD) process.

In the PGD method, the discharge parameters can be selected so that hollow cathode discharge (HCD) can occur inside the tube. HCD is characterized by very intense plasma (i.e., high discharge current). As a result, a high deposition rate can be achieved. In cases where the tube is very small, a magnetic field may be used to generate plasma inside the tube. In cases where the tube is long (e.g., 20 ft), it is impractical to house the tube for coating deposition in a vacuum chamber. Thus, the tube serves as both the vacuum chamber and the part to be coated. In both cases, PIID and PGD processes, the tube needs to be electrically isolated from ground and a negative voltage applied to the tube for the coatings to be deposited properly.

Unfortunately, in applications such as fossil-fired steam turbine boiler pipes that are several feet long, joined together and connected to large structures, it is impossible to electrically isolate the tubes. Thus, there is a need for a method that allows these tubes to be coated with hard, erosion and corrosion resistant coatings without isolating the tubes from ground, so that the service life of an in-service tube or pipe can be extended by preventing corrosion or erosion damage in its service.

### BRIEF SUMMARY OF THE INVENTION

These and other shortcomings of the prior art are addressed by the present invention, which provides a method for depositing coatings on a tubular structure that is not isolated from ground.

According to one aspect of the present invention, a system for depositing coatings on an inner surface of a tubular structure includes at least one pump for creating and maintaining a vacuum in the tubular structure, a meshed electrode adapted to be positioned in a center of the tubular structure, and a biased voltage power supply connected to the meshed electrode. The biased voltage power supply is adapted to apply a negative voltage to the meshed electrode such that the negative voltage causes a hollow cathode discharge inside the meshed electrode. The creation of the hollow cathode discharge causes ions to be drawn out of a mesh on the meshed electrode and accelerate onto an inner surface of the tubular structure, thereby coating the inner surface with a desired coating.

According to another aspect of the present invention, a method for depositing coatings on an inner surface of a tubular structure includes the steps of providing a system adapted to coat an inner surface of a tubular structure, cleaning the tubular structure, and depositing a coating on an inner surface of the tubular structure using the meshed electrode. The system includes a meshed electrode and a biased voltage power supply connected to the meshed electrode.

### BRIEF DESCRIPTION OF THE DRAWINGS

The subject matter that is regarded as the invention may be best understood by reference to the following description taken in conjunction with the accompanying drawing figures in which:

FIG. 1 is a schematic of a system for depositing coatings on a tube using a PIID process;

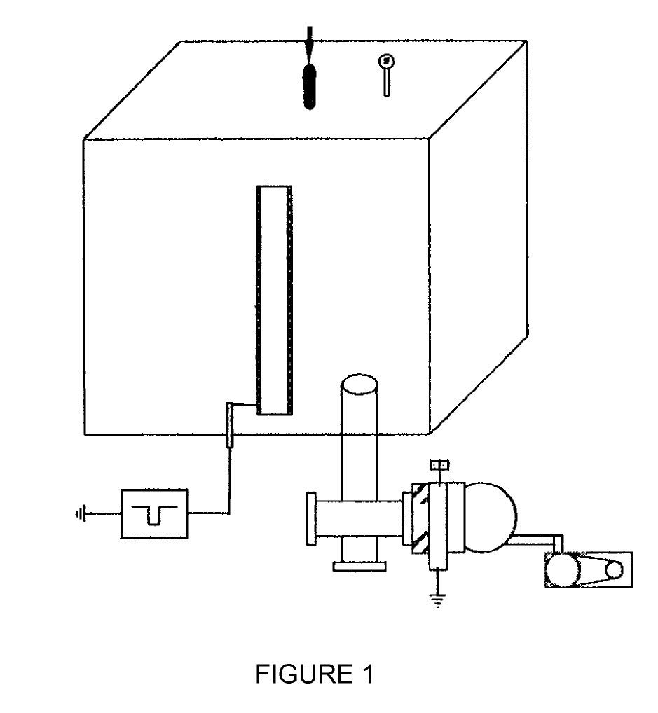

FIG. 2 is a schematic of a system for depositing coatings on a tube according to an embodiment of the present invention; and

FIG. 3 is a schematic of a system for depositing coatings on a tube according to an embodiment of the invention.

### DETAILED DESCRIPTION OF THE INVENTION

The method disclosed herein allows an inner diameter (ID) of tube or pipe that is electrically grounded or that cannot be isolated to be deposited with desired coatings. This technology enables the deposition of a pipe or a section of a pipe that connects to large structures. The deposited coating can be erosion resistant, wear resistant and corrosion resistant so that the service life of a tube or pipe can be extended by preventing corrosion or erosion damage in its service.

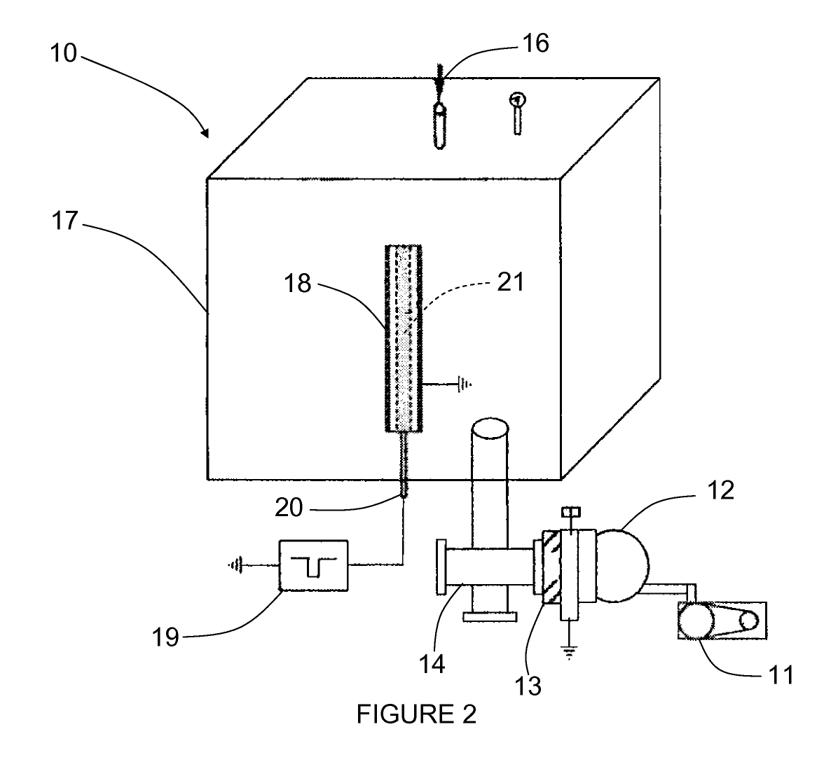

Referring to the drawings, an exemplary system for depositing coatings on an inner diameter (ID) surface of a tube or pipe according to the present invention is illustrated in FIG. 2 and shown generally at reference numeral 10. The system 10 includes pumps 11 and 12, a throttle valve 13, a four-way cross 14, a gas feed 16, a vacuum chamber 17 for containing a tube 18 during deposition of the coating, a biased/pulsed voltage power supply 19, a high voltage feed through 20, and a meshed electrode 21.

As shown, the meshed electrode 21 is positioned in the center of the tube 18 such that it does not contact the tube 18. The meshed electrode 21 has a mesh size in the range of 0.5 mm to 10 mm and has a diameter in the range of ⅛ to ½ the diameter of the tube 18. The meshed electrode 21 is connected to the biased power supply 19 while the tube 18 is electrically grounded. A negative voltage in the range of 0.5 kV to 7 kV is applied to the mesh electrode, thereby generating plasma so that the tube 18 can be deposited with a desired coating.

In performing the coating process, the vacuum chamber 17 is evacuated to at least 10⁻⁵ Torr and a working gas is fed in using the gas feed 16. Examples of gases to be used include Argon (Ar), Silane (SᵢH₄), and Acetylene (C₂H₂). The vacuum chamber is maintained at a pressure range of 5 millitorr to 100 millitorr. By adjusting the flow rate and the throttle valve 13, the vacuum chamber pressure may be maintained at about 10-20 millitorr.

When the mesh electrode is biased negatively with a train of pulse voltage, typically from 1 kV to 7 kV, hollow cathode discharge occurs inside the meshed electrode. The negative bias also draws the ions out of the mesh, and then accelerates them to the tube. It should be appreciated that other forms of discharge may be used. For example, DC discharge using a DC power supply and RF discharge using RF power may be used.

When Argon (Ar) gas is used, the tube may be sputter-cleaned. When a carbonaceous gas is used a diamond-like carbon (DLC) coating film may be deposited. A DLC film is typically referred to as an amorphous, hydrogenated carbon coating. It is a generic term and covers a wider range of coatings including Si-containing and N-containing carbon coatings. DLC coatings are preferred coatings because they can be deposited easily and uniformly. In addition, DLC coatings are hard, wear resistant, erosion resistant and corrosion resistant. Therefore, these coatings can be used for many applications. Generally, DLC coatings do not adhere well to a steel substrate; therefore, to increase the adhesion between the DLC and the tube 18, prior to the deposition of the DLC coating, an Si bond layer may be deposited using precursors such as SᵢH₄ or TMS (trimethylsilane).

Shown in Table 1 below, are example deposition parameters used for the system 10. As can be seen two tubes having a diameter of 2.5 inches and a length of 13 inches to 14 inches were deposited with a coating. A three step process was used for both tubes. The first was to sputter clean the tubes, the second was to deposit a bond layer, and the third was to deposit a coating.

The sputtering step took about 30 minutes for both tubes. Argon (Ar) was used and the flow rate was 45 sccm (standard cubic centimeters per minute). The vacuum system pressure was maintained at 15 millitoor.

A pulsed frequency of 500 Hz was used for sample 1 and 2000 Hz for sample 2, while the pulsed width was 201 μm. The peak pulsed voltage used was 4.1-5.6 kV for Sample 1 and 4.7 kV for sample 2.

Since a bond layer or adhesive layer is needed for DLC to adhere to steel substrates, a bond layer of TMS was used for sample 1 and HMDSO (Hexamethyldisiloxane) was used for sample 2. The bond layer deposition took 180 minutes for sample 1 and 60 minutes for sample 2. The other parameters were similar to those used in the sputtering step.

In the deposition step, a DLC layer was deposited on top of the bond layer to increase the hardness and C₂H₂ was used to form the DLC coating. The deposition parameters were similar to those used in the sputter cleaning and bond layer deposition steps.

Upon completion of the three step process, the coated tubes were sectioned along the centerline into halves for each tube to inspect the coatings using optical photograph and SEM (scanning electron microscopy). The tubes were measured in three locations, about 1 inch from the top, 1 inch from the bottom and in the center. These measurements are shown in Table 1.

TABLE 1

| | Tube | Sputter Cleaning | | | | | | Bond Layer | | | | | |
|---|---|---|---|---|---|---|---|---|---|---|---|---|---|
| | Size | | | | | Freq | | | | | | Freq | |
| Sam- | (Dia × | | | | | (Hz)/ | | | | | | (Hz)/ | |
| ple | Length) | Time | | Flow | Press | PW | Vb | Time | | Flow | Press | PW | Vb |
| # | (inch) | (Min) | Gas | (sccm) | (mtorr) | (μs) | (Kv) | (Min) | Gas | (sccm) | (mtorr) | (μs) | (Kv) |
| 1 | 2.5 × 13.5 | 30 | Ar | 45 | 15 | 500/20 | 4.1-5.6 | 180 | TMS | 10 | 15 | 500/20 | 4.1 |
| 2 | 2.5 × 14 | 30 | Ar | 45 | 15 | 2000/20 | 4.7 | 60 | HMDSO | 15 | 15 | 2000/20 | 4.7 |

| | | | | | | Measurements | | | | |
|---|---|---|---|---|---|---|---|---|---|---|
| Coating | | | | | | Thickness | Thickness | Thickness | Thickness | |
| Time | | Flow | Press | Freq (Hz)/ | Vb | (μm) | (μm) | (μm) | (μm) | |
| (hrs) | Gas | (sccm) | (mtorr) | PW (μs) | (Kv) | (Top) | (center) | (Bottom) | (Average) | Comments |
| 3 | C2H2 | 60 | 15 | 500/20 | 5 | 3.93 | 2.84 | 2.43 | 3.07 | Coating looks |
| | | | | | | | | | | very good |
| 1 | C2H2 | 50 | 15 | 2000/20 | 4.7 | 7.48 | 5.68 | 7.20 | 6.79 | Coating looks |
| | | | | | | | | | | very good |

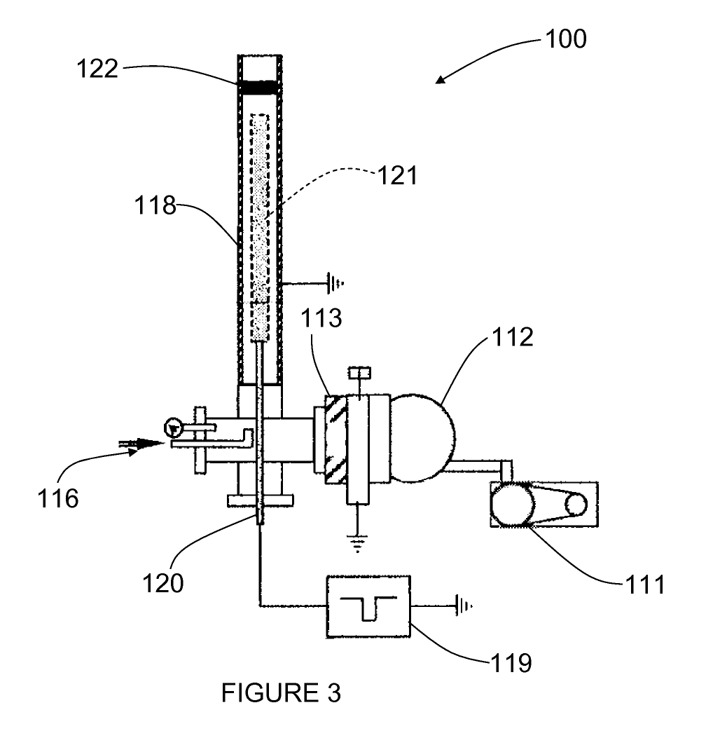

Referring to FIG. 3, system 100 includes pumps 111 and 112, a throttle valve 113, a four-way cross 114, a gas feed 116, a tube 118 to be coated, a biased/pulsed voltage power supply 119, a high voltage feed through 120, and a meshed electrode 121. The system 100 further includes an end cap/plug 122. Unlike system 10, system 100 does not require a separate vacuum chamber. Instead, by using the plug 122, the tube 118 acts as its own vacuum chamber.

Like system 10, system 100 uses a meshed electrode 121 connected to a biased power supply 119 while the tube 18 is electrically grounded. As a negative voltage is applied to the mesh electrode, plasma is generated to allow the tube 18 to be deposited with a desired coating.

The foregoing has described a system and method for depositing coatings on an inner surface of a tubular structure. While specific embodiments of the present invention have been described, it will be apparent to those skilled in the art that various modifications thereto can be made without departing from the spirit and scope of the invention. Accordingly, the foregoing description of the preferred embodiment of the invention and the best mode for practicing the invention are provided for the purpose of illustration only and not for the purpose of limitation.

We claim:

1. A system for depositing coatings on an inner surface of a tubular structure, comprising:
(a) at least one pump for creating and maintaining a vacuum in the tubular structure;
(b) a meshed electrode adapted to be positioned in a center of the tubular structure;
(c) a biased voltage power supply connected to the meshed electrode, the biased voltage power supply being adapted to apply a negative voltage to the meshed electrode such that the negative voltage causes a hollow cathode discharge inside the meshed electrode; and
(d) wherein the creation of the hollow cathode discharge causes ions to be drawn out of a mesh on the meshed electrode and accelerate onto an inner surface of the tubular structure, thereby coating the inner surface with a desired coating.

2. The system according to claim 1, wherein the meshed electrode is positioned in the center of the tubular structure such that the meshed electrode does not contact the inner surface of the tubular structure.

3. The system according to claim 1, wherein the mesh of the meshed electrode has a mesh size of about 0.5 mm to about 10 mm.

4. The system according to claim 1, wherein the meshed electrode has a diameter of about one-eighth to about one-half the diameter of the tubular structure.

5. The system according to claim 1, wherein the application of a negative voltage to the meshed electrode generates a plasma.

6. The system according to claim 1, wherein the biased power supply applies a negative voltage of about 0.5 kV to about 7 kV.

7. The system according to claim 1, further including a vacuum chamber, wherein the tubular structure is placed in the vacuum chamber and the at least one pump creates a vacuum in the chamber, thereby creating and maintaining a vacuum in the tubular structure.

8. The system according to claim 1, wherein the at least one pump is operably connected to the tubular structure such that the tubular structure acts as a vacuum chamber.

9. The system according to claim 1, further including a throttle valve operably connected to the at least one pump, the throttle valve being adjustable and adapted to maintain a vacuum of a desired pressure.

10. The system according to claim 1, further including a gas feed for supplying a desired gas to be used in coating the inner surface.

11. A method for depositing coatings on an inner surface of a tubular structure, comprising the steps:
(a) providing a system adapted to coat an inner surface of a tubular structure, the system having:
(i) a meshed electrode; and
(ii) a biased voltage power supply connected to the meshed electrode;
(b) cleaning the tubular structure; and
(c) depositing a coating on an inner surface of the tubular structure using the meshed electrode.

12. The method according to claim 11, wherein the step of cleaning is performed by sputter cleaning the tube.

13. The method according to claim 12, wherein sputter cleaning is performed using Argon gas.

14. The method according to claim 11, further including the step of depositing a bond layer on the inner surface of the tubular structure.

15. The method according to claim 14, wherein the bond layer is an Si bond layer.

16. The method according to claim 11, further including the step of applying a vacuum to the tubular structure.

17. The method according to claim 16, wherein the vacuum is applied using at least one pump.

18. The method according to claim 11, further including the step of using the biased power supply to apply a negative voltage to the meshed electrode such that the negative voltage causes a hollow cathode discharge inside the meshed electrode which causes ions to be drawn out of a mesh on the meshed electrode and accelerate onto an inner surface of the tubular structure, thereby coating the inner surface with a desired coating.
